(19) United States
(12) Patent Application Publication
(10) Pub. No.: US 2026/0026131 A1
(43) Pub. Date: Jan. 22, 2026

(54) GaAsSb Core-Shell Nanowire Photodetector Grown on Graphitic Substrate and Preparation Method Thereof

(71) Applicant: North Carolina A&T State University, Greensboro, NC (US)

(72) Inventors: Shanthi Iyer, Greensboro, NC (US); Hirandeep Reddy Kuchoor, Greensboro, NC (US); Jia Li, Greensboro, NC (US)

(73) Assignee: North Carolina A&T State University, Greensboro, NC (US)

(21) Appl. No.: 19/270,692

(22) Filed: Jul. 16, 2025

Related U.S. Application Data
(60) Provisional application No. 63/672,290, filed on Jul. 17, 2024.

(51) Int. Cl. H10F 77/14; H10F 30/22; H10F 71/00; H10F 77/124

(52) U.S. Cl. CPC H10F 77/1437; H10F 30/22; H10F 71/1272; H10F 77/1248

(57) ABSTRACT

The presently disclosed subject matter relates generally to GaAsSb NWs (NW) grown on a graphitic substrate, to methods of growing such NWs, and to use of such NWs in applications such as flexible near infrared photodetector.

### CROSS-REFERENCE TO RELATED APPLICATION

The present application claims priority from U.S. Provisional Patent Application Ser. No. 63/672,290 filed on 17 Jul. 2024, the entire content of which is incorporated herein by reference.

### STATEMENT REGARDING FEDERAL FUNDING

This invention was made with Government support under W911NF-22-1-0114 awarded by the Army Research Office. The Government has certain rights in this invention.

### FIELD

This disclosure generally relates to nanowires (NWs) including gallium (Ga), arsenic (As) and antimony (Sb) grown on a graphitic substrate, such as, for example, GaAsSb core-shell NWs; methods of growing such NWs on a graphitic substrate; and methods of using such NWs. The presently disclosed subject matter furthers photodetector (PD) devices capable of use in the near-infrared (NIR) region employing NWs.

### BACKGROUND

One-dimensional (1D) semiconductor NWs can be building blocks for nanophotonic integrated devices, due to their superior light trapping characteristics and high crystal quality. Heterogeneous integration of NWs with a two dimensional (2D) material provides an excellent platform for flexible device growth, due to their weak van der Waal interactions, and offers cost effective opportunities for a broad range of advanced generation flexible optoelectronic device applications, such as aerial infrared tracking, night vision, wearable devices, mobile applications, medical detection, and petroleum exploration.

Moreover, semiconductor NWs are of interest due to their large aspect ratio, which enables relaxation of lattice mismatch constraints, and enhanced light trapping features. This offers unique opportunities to integrate nanophotonic devices, such as group III-V compound semiconductors, with electronic devices on a silicon (Si) platform. Group III-V NWs that include Gallium (Ga), Arsenic (As) and/or Antimony (Sb) have attracted considerable attention, due to their high absorption coefficient, superior carrier mobility characteristics, as well as a bandgap tunability ranging from 870 nm to 1700 nm depending on the combination of the metallic components.

The ability of group III-V NWs to tolerate larger mismatch offers an opportunity to integrate these NW materials with 2D materials. Notably, graphene shows exceptional electrical, mechanical and optical properties, while being cost-effective and relatively easy to produce. Epitaxial growth of NWs on graphene occurs via weak van der Waal forces, in contrast to the epitaxial growth of NW via strong covalent bonding observed in traditional substrates (e.g. Si or GaAs). However, graphene's low surface energy, which is two orders of magnitude lower than conventional NW substrates such as Si and GaAs, poses a significant challenge to growing NWs on its surface. In particular, the growth of high-yield vertical semiconductor NWs on graphene faces challenges due to: (i) the small bond length of graphene compared to group III-V semiconductor materials, (ii) differences in the adsorption energies of the group III-V constituents on different sites of the graphene lattice, and (iii) the chemically inert nature of graphene, corresponding to a low surface energy, and resulting in the formation of droplets with a large contact angle that is not conducive to vertical NW growth. Hence, there are few reports on the growth of semiconductor NWs of any composition on graphene.

Given the foregoing, there still is a need to effectively grow NWs on a graphitic substrate, and particularly ternary NWs including Ga, As, and Sb grown on a graphitic substrate, as well as methods of growing such NWs, are still desired. The disclosed systems and methods are directed to overcoming one or more of the problems set forth above.

### SUMMARY

In one aspect, the disclosed technology relates to a core-shell axial NW comprising: a base and a tip; a core extending along a NW axis from the base to the tip; and a shell enclosing the core; wherein the core comprises more than one segment. In some embodiments, the core-shell axial NW has a length ranging from about 800 nm to about 2500 nm. In some embodiments, the core comprises n-type GaAs. In some embodiments, the shell comprises intrinsic-GaAs₁₋ₐSbₐ, wherein a is from about 0.25 to about 0.3. In some embodiments, the core has a diameter from about 60 nm to about 80 nm. In some embodiments, wherein the shell has a thickness from about 25 nm to about 50 nm. In some embodiments, the core comprises an Sb content gradient, wherein Sb content decreases from the base to the tip.

In some embodiments, the core comprises three segments, wherein a first segment comprises Sb content of up to 40%, a second segment comprises Sb content of up to 30%, and a third segment comprises Sb content of up to 20%, wherein the first segment is disposed at the base, the third segment is disposed at the tip, and the second segment is positioned between the first segment and the second segment. In some embodiments, the core further comprises a top segment comprising intrinsic-GaAs₁₋ₙSbₙ, wherein n is from about 0.15 to about 0.20.

In some embodiments, the shell enclosing the core is a first shell and the core-shell axial NW further comprises a second shell encloses the first shell, wherein the second shell comprises p-type GaAs_{1-b}Sb_{b}, wherein b is from about 0.2 to about 0.25. In some embodiments, wherein the second shell has a thickness from about 25 nm to about 50 nm. In some embodiments, the NW further comprises a passivation layer enclosing the second shell, wherein the passivation layer is AlGaAs/GaAs. In some embodiments, the passivation layer has a thickness from about 10 nm to about 25 nm.

In another aspect, the disclosed technology relates to a NW ensemble comprising at least one core-shell axial NW of this document, wherein the NW ensemble has a NW density from about 25 μm⁻² to about 70 μm⁻².

Yet, in another aspect, the disclosed technology relates to a photodetector device comprising at least one core-shell axial NW of this document.

In another aspect, the disclosed technology relates to a method of fabricating a core-shell axial NW, the method comprising: (a) forming a NW stem on a growth substrate by depositing first precursor sources on the growth substrate; (b) growing a NW core on the NW stem by depositing the first precursor sources; (c) surrounding the NW core with a shell by depositing a second precursor sources on the NW core; wherein the first precursor sources comprise gallium (Ga), arsenic (As), antimony (Sb), and gallium telluride (GaTe), wherein the second precursor sources comprise gallium (Ga), arsenic (As), antimony (Sb), and intermittent gallium telluride (GaTe), and wherein the NW core comprises more than one segment deposited sequentially on the NW stem.

In some embodiments, the steps (a)-(c) comprise using molecular beam epitaxy to deposit the first and the second precursor sources. In some embodiments, the growth substrate is monolayer graphene. In some embodiments, the NW core comprises n-type GaAsSb, wherein the n-type GaAsSb has an Sb content gradient from a NW base to a NW tip, wherein Sb content decreases from a segment disposed at the NW base towards the tip In some embodiments, before step (c), the method further comprises: growing a top segment on top of the NW core by depositing the second precursor sources using molecular beam epitaxy to deposit the second precursor sources, wherein the top segment is intrinsic-GaAs₁₋ₙSbₙ, wherein n is from about 0.15 to about 0.20. In some embodiments, the shell comprises intrinsic-GaAs₁₋ₐSbₐ, wherein a is from about 0.25 to about 0.3.

In some embodiments, after step (c) further comprising; surrounding the shell with a second shell by depositing third precursor sources on the shell using molecular beam epitaxy to deposit the third precursor sources, wherein the shell surrounding the core is a first shell, and wherein the third precursor sources comprise gallium (Ga), arsenic (As), and antimony (Sb), wherein the second shell is GaAsSb doped with beryllium (Be). In some embodiments, the growth substrate is pre-treated with oxygen plasma by exposing the growth substrate to oxygen plasma from about 60 seconds to about 100 seconds. In some embodiments, the forming the NW stem of step (a) is carried out at a temperature ranging from about 530° C. to about 560° C. at a growth duration of about 5 minutes.

In some embodiments, the growing the NW core of step (b) is carried out at a temperature ranging from about 550° C. to about 600° C. at a growth duration of about 60 minutes In some embodiments, the growing the NW core of step (b) comprises depositing Ga at a beam equivalent pressure from about 1×10⁻⁷ Torr to about 2×10⁻⁷ Torr. In some embodiments, the growing the NW core of step (b) comprises depositing As to Ga beam equivalent pressure ratio from about 15 to about 25. In some embodiments, the growing the NW core of step (b) comprises depositing Sb to Ga beam equivalent pressure ratio from about 15 to about 25.

In some embodiments, after the surrounding the first shell with the second shell step, further comprising: surrounding the second shell with a passivation layer by depositing fourth precursor sources on the second shell using molecular beam epitaxy, wherein the fourth precursor sources comprise aluminum (Al), gallium (Ga), and arsenic (As). In some embodiments, the passivation layer is grown at temperature ranging from about 450° C. to about 470° C. at a growth duration of about 8 minutes. In some embodiments, the depositing fourth precursor step comprises depositing Ga at a beam equivalent pressure from about 1×10⁻⁷ Torr to about 2×10⁻⁷ Torr or depositing As at a beam equivalent pressure from about 1.5×10⁻⁶ Torr to about 5×10⁻⁶ Torr.

Any compositions or methods provided herein can be combined with one or more of any of the other compositions and methods provided herein.

### BRIEF DESCRIPTION OF THE DRAWINGS

FIG. 1 illustrates a schematic that depicts routes for fabricating various high-density GaAsSb NW architectures on graphene substrate according to the present disclosure.

FIG. 2 illustrates a schematic of traditional core-shell (TCS) and hybrid core-shell (HCS) NWs of the present disclosure.

FIGS. 3A and 3B illustrates a band diagram and core composition schematic for HCS NW of the present disclosure.

FIGS. 4A and 4B depict scanning electron microscope (SEM) images of TCS (FIG. 4A) and HCS (FIG. 4B) NWs of the present disclosure.

FIG. 5 depicts length and diameter distribution of TCS and HCS NW of the present disclosure.

FIGS. 6A-6E illustrate SEM images (FIGS. 6A-6D) of various embodiments of GaAsSb NWs on graphene substrate and density plot (FIG. 6E) corresponding to NW density for varied growth temperatures and pausing durations.

FIGS. 7A-7D illustrate XPS C 1s spectra (FIGS. 7A and 7B), Raman spectra (FIG. 7C) of monolayer graphene, and a plot (FIG. 7D) showing variation of I_{D}/I_{G} and I_{2D}/I_{G} ratios under different plasma durations.

FIGS. 8A-8C illustrate SEM images of GaAsSb NWs on plasma treated graphene substrate under various plasma treatment conditions.

FIG. 9 illustrates a plot variation of NW density grown under different plasma durations.

FIG. 10 illustrates a plot of dimension and growth rate of the GaAsSb NW core at different V/III beam equivalent pressure (BEP) ratios.

FIG. 11 illustrates a plot showing GaAsSb NW density.

FIG. 12 illustrates 4K temperature photoluminescence (PL) spectra of different GaAsSb NWs of the present disclosure.

FIG. 13A-13J illustrate EDS line scan (FIGS. 13A-13C) overlaid with high-angle annular dark-field scanning transmission electron microscope (HAADF STEM), transmission electron microscopy (TEM) analysis (FIGS. 13D-13F) of top, middle, and bottom segment of GaAsSb NW, energy dispersive X-ray spectroscope (EDS) line scan (FIG. 13G) along the axis of the NW, and selected area electron diffraction (SAED) patterns (FIGS. 13H-13J) of individual segments of GaAsSb NW of the present disclosure.

### DETAILED DESCRIPTION

The following discussion omits or only briefly describes conventional features of the disclosed technology that are apparent to those skilled in the art. Reference to various embodiments does not limit the scope of the claims attached hereto. Additionally, any examples set forth in this specification are intended to be non-limiting and merely set forth some of the many possible embodiments for the appended claims. Further, particular features described herein can be used in combination with other described features in each of the various possible combinations and permutations. A person of ordinary skill in the art would know how to make and use the disclosed technology, in combination with routine experiments, to achieve other outcomes not specifically disclosed in the examples or the embodiments.

Unless otherwise specifically defined herein, all terms are to be given their broadest possible interpretation, including meanings implied from the specification as well as meanings understood by those skilled in the art and/or as defined in dictionaries, treatises, etc. Unless defined otherwise, all technical and scientific terms used herein have the same meaning as commonly understood by one of ordinary skill in the art in the field of the disclosed technology. It must also be noted that, as used in the specification and the appended claims, the singular forms “a,” “an” and “the” include plural referents unless otherwise specified, and that the terms “includes” and/or “including,” when used in this specification, specify the presence of stated features, elements, and/or components, but do not preclude the presence or addition of one or more other features, steps, operations, elements, components, and/or groups thereof. Additionally, methods, equipment, and materials similar or equivalent to those described herein can also be used in the practice or testing of the disclosed technology.

As used herein, “about” when used in connection with a numeric value, is intended to include values that are close to, but not exactly, the number to the nearest significant figure. For example, a numerical value of “about 5” may include values ranging from 4.6 to 5.4. Alternatively, the term “about” with respect to a numerical value means plus or minus 10% of the numerical value, unless indicated otherwise.

As used herein, various terms are used such as “first,” “second,” and the like. These terms are words of convenience in order to distinguish between different elements, and such terms are not intended to be limiting as to how the different elements may be utilized.

As used herein, “nanowire” refers to an anisotropic wire or tube-like structure. NWs are essentially one-dimensional with nanometer dimension in width or diameter of 1-1000 nm, including for example 1-500 nm or 1-300 nm. The length of NWs is typically in the range of a few 100 nm to up to 10 μm. NWs may have a length-to-diameter aspect ratio of at least 2, at least 5, at least 10, at least 50, at least 100, at least about 250, or at least about 500. Generally, an aspect ratio of >5 is considered “high” for the NWs of the present application. It is further to be understood that NW described herein can be cylindrical or substantially cylindrical. A NW described herein can also be faceted, as opposed to having a continuously curved circumference.

As used herein “axial NW” refers to a NW containing the active components in an axial configuration (e.g. axially stacked). As disclosed herein, in some embodiments GaAsSb axial NWs have a uniform Sb content. In some embodiments, axial NW have varying Sb content defined as GaAs_{1-c}Sb_{c}, wherein c is from about 0.05 to about 0.2, such as, for example, 0.07. In other embodiments, GaAs_{1-c}Sb_{c} axial NWs have a stem GaAs₁₋ₛSbₛ where s is from about 0.3 to about 0.5 and an upper region having varying Sb (and As) content. In some embodiments, the “stem region” is generally the “bottom” or the “base” of the NW, i.e. the area of the NW that is adjacent to the substrate; the “upper region” is generally that area of the NW that is not adjacent to the substrate and is at the “top” or “tip” of the NW, relative to the substrate being at the “bottom” or “base.”

As used herein “core-shell NW” or “axial core-shell NW” refers to a NW containing the active components in a layered configuration, i.e., having one or more “core” component extending in a length-wise/axial direction and a “shell” component enclosing or covering the core component. In various embodiments, the core component and the shell component may be the same or different. In some embodiments, the core and shell components may comprise differently doped GaAsSb components (i.e., n-type, p-type, or i-type). As used herein, n-type refers to a structure where the structure is dope with electron donor impurities to have excess negative charge carriers, i.e., electrons. As used herein, p-type refers to a structure where the structure is dope with electron acceptor impurities to have excess positive charge carriers, i.e., holes. As used herein, i-type, or intrinsic-type refers to an undoped semiconductor that acts as a buffer region having a low electrical conductivity.

As used herein “hybrid NW” refers to a NW containing structural aspects of both axial only NW and core-shell NW. For example, a hybrid NW may include multiple GaAsSb axial “core” segments along axial, growth direction, where different segments may comprise different amounts of Sb (and As) content.

As used herein, an “array” or an “ensemble” of NWs, refers to a group of the NWs on a surface. The “density” of an ensemble refers to the percentage of the area of the surface that is occupied by the objects of the ensemble (as opposed to being vacant or occupied by some other item). An “ordered” ensemble refers to an ensemble in which the arrangement of the objects within the ensemble follows a pattern or substantially follows a pattern (i.e., within about 20%, about 10%, or about 5% deviation from the pattern). For example, the objects of an “ordered” ensemble can be arranged in regularly spaced rows and columns.

As used herein, the term “room temperature” means an indoor temperature of from about 20° C. to about 25° C.

In some embodiments, the NWs disclosed herein may be coated with a passivation layer, which suppresses surface states of the NW, wherein the passivation layer includes a material having a higher band gap compared to GaAsSb NW. In some embodiments, the passivating layer optionally includes GaAs, where the NWs disclosed herein are passivated by growing a GaAs layer over the NW shell. The passivation layer generally exemplified herein is GaAs, but those of skill in the art can prepare passivation layers having different compositions, including, but not limited to AlGaAs. In some embodiments, the GaAs or AlGaAs layer is grown by a vapor-solid technique. In some embodiments, passivated axial NWs grown on graphene as disclosed herein exhibit photoluminescence emission at 1.28 eV at 4K, and 1.19 eV at room temperature.

The passivation layer generally surrounds (or covers or “overcoats”) or substantially surrounds the NWs. As understood by one of ordinary skill in the art, a passivation layer that “surrounds” or “substantially surrounds” (or “covers” or “substantially covers” or “overcoats” or “substantially overcoats”) the NW can surround or substantially surround (or cover or substantially cover or overcoat or substantially overcoat) the circumference of the NW, such that the layer surrounds or substantially surrounds (or covers or overcoats) the NW radially. The layer may also surround or substantially surround (or cover or substantially cover or overcoat or substantially overcoat) the NW on the ends or faces of the NW longitudinally (i.e., at the ends of the “length” or “long dimension” of the NW). Additionally, the passivation layer can surround (or cover or overcoat) at least about 75%, at least about 80%, at least about 85%, at least about 90%, at least about 95%, at least about 98%, or at least about 99% of the relevant surface or surfaces of the NW, based on area. Thus, in some cases, the passivation layer completely or substantially completely surrounds, covers, or overcoats the NW.

In some embodiments, the NWs are grown and align vertically or substantially vertically grown or aligned, relative to the substrate on which the NWs are disposed or grown, where the “vertical” direction corresponds to a direction perpendicular to the surface of the substrate. As used herein, the phrase “substantially vertically aligned” refers to an orientation of a plurality of anisotropic objects (e.g., NWs) in a population of the objects, wherein at least about 60 percent, at least about 70 percent, at least about 80 percent, at least about 90 percent, at east 95 percent, or at least 99 percent of the objects (e.g., NWs) of the population have a vertical or substantially vertical orientation. A “vertical orientation” refers to an orientation wherein the long axis of an anisotropic object (e.g., a NW) forms an angle (θ) of less than about 30 degrees, less than about 15 degrees, or less than about 10 degrees with a vertical line or direction described herein.

Similarly, anisotropic objects that are “substantially aligned” without reference to a specific direction (e.g., a vertical direction) of alignment are aligned with reference to an average orientation or direction of alignment of the population of anisotropic objects. Further, at least about 60 percent, at least about 70 percent, at least about 80 percent, or at least about 90 percent of the objects (e.g., NWs) of the population have an orientation or alignment wherein the long axis of the anisotropic object (e.g., a NW) forms an angle (θ) of less than about 30 degrees, less than about 15 degrees, or less than about 10 degrees with an average orientation or direction described hereinabove.

The NW of the present disclosure are grown on a graphitic substrate. Graphitic substrates include, but are not limited to graphene or derivatives thereof, such as graphene oxide or graphane. Graphene includes a single layer of graphene (monolayer graphene) or multiple layers of graphene (multilayer graphene) or derivatives thereof. The term “monolayer” refers to a layer that is one atom thick; multilayer graphene refers to more than one layer of graphene, such as 5 layers, 10 layers, 15 layers or more.

Accordingly, the present disclosure relates to compositions including one or more NWs on graphitic substrates. NWs have a variety of uses, for example, they may be used in optoelectronic or photodetection devices.

### Growth of High-Density GaASb Nanowire Grown on Graphene Substrate

The growth of high density GaAsSb axial NWs was carried out on a graphene substrate in a solid-source plasma-assisted VEECO EPI 930 Molecular Beam Epitaxy (MBE) system. First, chemical vapor deposition (CVD) grown monolayer graphene (MLG) grown on 25 μm thick copper (Cu) foil was coated with poly(methylmethacrylate) and etched from the copper substrate using a bubble transfer process, after which the poly(methylmethacrylate)-monolayer graphene (PMMA-MLG) was transferred onto a pre-cleaned SiO₂/n-Si substrate. The PMMA-MLG/SiO₂/n-Si sample was treated with O₂-plasma to remove the top PMMA layer. Further details regarding the subjecting a graphene substrate with O₂-plasma are illustrated and described, for example, in U.S. Pat. No. 11,384,286 to Iyer et al., the entire contents of which are incorporated herein by reference. Next, the PMMA-MLG/SiO₂/n-Si sample was treated with an O₂-plasma power of about 1 W for a duration from about 10 seconds to about 100 seconds, about 20 seconds to about 90 seconds, about 30 seconds to about 80 seconds, about 40 seconds to about 70 seconds, about 50 to about 60 seconds, or at about 10 seconds, about 20 seconds, about 30 seconds, about 40 seconds, about 50 seconds, about 60 seconds, about 70 seconds, about 80 seconds, about 90 seconds, or at about 100 seconds.

Afterwards, the O₂-plasma treated substrate was baked for about 1 hour at 80° C. in the EPI 930 MBE system and pressure set to about 10⁻⁷ Torr and transferred to the growth chamber, and the growth was initiated by simultaneously introducing Ga, As, Sb, and GaTe sources, where Ga was utilized as group III source, As and Sb fluxes were utilized as group V sources, and Te from GaTe was utilized as the n-type dopant. Further details regarding the growth of NWs by molecular beam epitaxy are illustrated and described, for example, in U.S. Pat. No. 11,905,622 to Iyer et al., and U.S. Pat. No. 11,384,286 to Iyer et al., the entire contents of which are incorporated herein by reference.

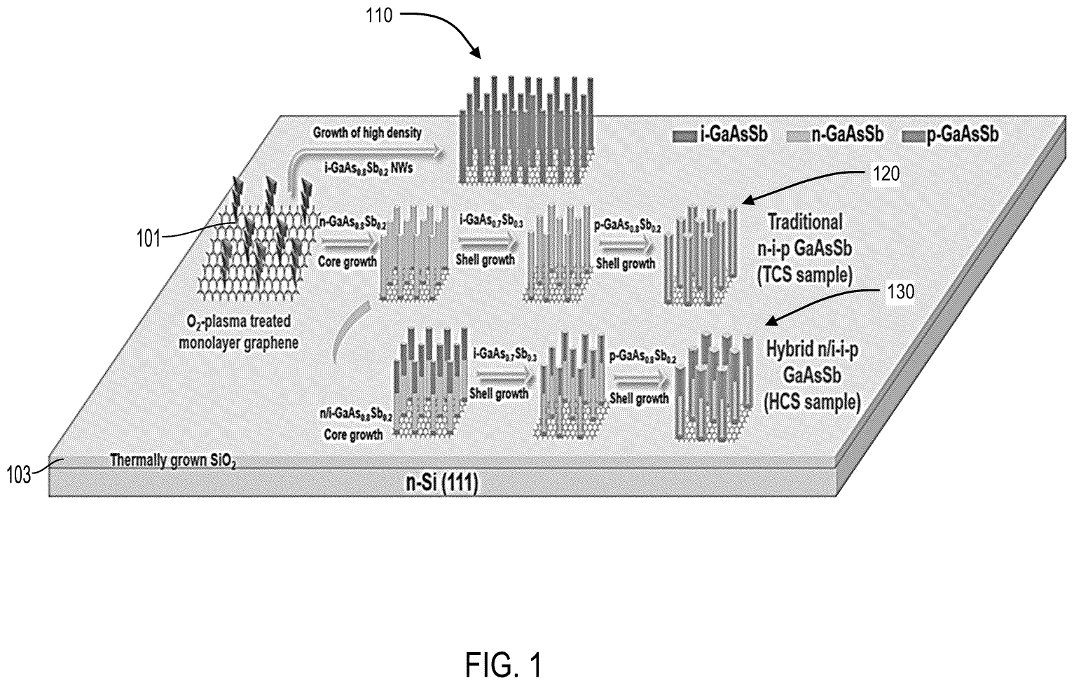

Now referring to FIG. 1, growth of various configurations of high-density GaAsSb NWs is disclosed herein. In various embodiments, O₂-plasma treated monolayer graphene (MLG) 101 on SiO₂/n-Si substrate 103 may serve as the nucleation sites for growth of an ensemble of high-density axial i-GaAsSb NW 110, traditional core-shell (TCS) n-i-p GaAsSb NW 120, or hybrid core-shell (HCS) n/i-i-p GaAsSb 130. NW. As used herein “n-i-p” configuration refers to a NW configuration having n-type GaAsSb core, i-type GaAsSb first shell enclosing the core, and p-type GaAsSb second shell enclosing the first shell. Similarly, “n/i-i-p” configuration refers to a core comprising n-type and i-type GaAsSb (“n/i”) surrounded by i-type GaAsSb first shell enclosing the “n/i” core, and p-type GaAsSb second shell enclosing the first shell.

In various embodiments, axial GaAs NW 110 may be grown by heating the substrate to about 540 C° to initiate the growth of the Te-doped GaAsSb stem. The surfactant property of the Te dopant serves to precisely control the droplet angle and reducing the formation of horizontal NWs and 2D crystallites on the graphene surface. In some embodiments, the GaAsSb stem may be grown at a temperature ranging from about 520° C. to about 560° C., about 525° C. to about 555° C., about 530° C. to about 550° C., about 535° C. to about 545° C., or at about 520° C., about 525° C., about 530° C., about 535° C., about 540° C., about 545° C., about 550° C., about 555° C. or about 560° C. In some embodiments, the GaAsSb stem may be grown at duration ranging from about 1 minute to about 10 minutes, about 3 minutes to about 8 minutes, about 5 minutes to about 6 minutes, or at about 1 minute, about 2 minutes, about 3 minutes, about 4 minutes, about 5 minutes, about 6 minutes, about 7 minutes, about 8 minutes, about 9 minutes, or about 10 minutes.

In this step, precursor sources may be Ga, As, Sb, and GaTe. In some embodiments, Ga source may be introduced at BEP of about 1×10⁻⁷ torr to about 2×10⁻⁷ torr, As source may be introduced at BEP of about 1.5×10⁻⁶ torr to about 5×10⁻⁶ torr, Sb source may be introduced at BEP of about 5.0×10⁻⁷ torr to about 5×10⁻⁶ torr. In some embodiments GaTe source may be introduced at temperature of about 530° C. After the initiation of the stem growth, the temperature may be ramped to about 580° C. to initiate the intrinsic-GaAs₁₋ₘSbₘ (i-GaAs₁₋ₘSbₘ) NW growth. In this step, precursor sources may be Ga, As, Sb, and intermittent GaTe supply. In the growth of GaAs₁₋ₘSbₘ NW step, precursor sources may be Ga, As, Sb, and intermittent GaTe supply. Intermittent GaTe supply is provided to introduce n-type Te dopant to GaAsSb. As used herein, “intermittent GaTe supply” may refer to introducing GaTe supply at a defined duration or pulse.

In some embodiments, for a 10-minute growth of i-GaAs₁₋ₘSbₘ NW, GaAsSb may be grown for about 2 minutes, and n-GaAsSb (by introducing GaTe) for 2 seconds. In some embodiments, GaTe may be applied for 10 minutes at 2 minutes/2 seconds GaAsSb/n-GaAsSb, (doped with GaTe) pulse cycles. In some embodiments, for a 5-minute growth of i-GaAsSb NW, GaAsSb may be grown for about 1 minutes, and n-GaAsSb (by introducing GaTe) for 2 second. In some embodiments, GaTe may be applied for 5 minutes at a 1 minutes/2 seconds GaAsSb/n-GaAsSb pulse cycles. In some embodiments, intermittent GaTe supply may be provided by applying GaTe source at a constant pulse every 1 second, 2 seconds, 3 seconds, about 4 seconds, or 5 seconds. In some embodiments, Ga source may be introduced at BEP of 1.2×10⁻⁷ torr, As source may be introduced at BEP of 2.12×10⁻⁶ torr, and Sb source may be introduced at BEP of 5.28×10⁻⁷ torr.

In some embodiments, the i-GaAs₁₋ₘSbₘ NW may be grown at a temperature ranging from about 550° C. to about 600° C., about 555° C. to about 595° C., about 560° C. to about 590° C., about 565° C. to about 585° C., about 570° C., about 580° C., or at about 550° C., about 555° C., about 560° C., about 565° C., about 570° C., about 575° C., about 580° C., about 585° C., about 590° C., about 595° C., or at about 600° C. In some embodiments, the i-GaAs₁₋ₘSbₘ NW is grown at a duration ranging from about 30 minutes to about 90 minutes, about 40 minutes to about 80 minutes, about 50 minutes to about 70 minutes, or at about 30 minutes, about 35 minutes, about 40 minutes, about 45 minutes, about 50 minutes, about 55 minutes, about 60 minutes, about 65 minutes, about 70 minutes, about 75 minutes, about 80 minutes, about 85 minutes or about 90 minutes.

In various embodiments, i-GaAs₁₋ₘSbₘ NW may have m ranging from about 0.15 to about 0.2. In various embodiments, the length of i-GaAs₁₋ₘSbₘ NW may range from about 0.6 μm to about 1.3 μm and diameter from about 65 nm to about 85 nm. In some embodiments, the i-GaAs₁₋ₘSbₘ NW may have length-to-diameter aspect ratio from about 7 to about 20.

As seen further in FIG. 1, two configurations of core-shell (CS) GaAsSb NWs may be grown using the disclosed method. In various embodiments, an ensemble of traditional core shell (TCS) n-i-p GaAsSb NW 120 may be initiated by growing from a stem or a base, to a tip, an n-type GaAs₁₋ₓSbₓ (n-GaAs₁₋ₓSbₓ) core. In some embodiments, GaAsSb stem growth for the growth of TCS NW may be same as the method described above for the growth of i-GaAs₁₋ₘSbₘ NW.

In some embodiments, after the stem growth, n-GaAs₁₋ₓSbₓ core may be grown by depositing Ga, As, Sb, and GaTe precursor sources. In some embodiments, Ga source may be introduced at BEP from about 1.0×10⁻⁷ torr to about 2×10⁻⁷ torr, As source may be introduced at BEP from about 2.12×10⁻⁶ torr to about 1.85×10⁻⁶ torr, Sb source may be introduced at BEP from about 5.28×10⁻⁷ torr to about 7.92×10⁻⁷ torr, and GaTe source may be introduced at a cell temperature of 530° C. In some embodiments, n-GaAsSb NW core may be grown with a V/III BEP of 22. In some embodiments, V/III (i.e., As to Ga or Sb to Ga) BEP may be from about 15 to about 25, or at about 15, about 16, about 17, about 18, about 19, about 20, about 21, about 22, about 23, about 24 or about 25.

The n-GaAs₁₋ₓSbₓ core may be grown at a temperature ranging from about 550° C. to about 600° C., about 555° C. to about 595° C., about 560° C. to about 590° C., about 565° C. to about 585° C., about 570° C., about 580° C., or at about 550° C., about 555° C., about 560° C., about 565° C., about 570° C., about 575° C., about 580° C., about 585° C., about 590° C., about 595° C., or at about 600° C. In some embodiments, the n-GaAs₁₋ₓSbₓ core is grown at duration ranging from about 30 minutes to about 90 minutes, about 40 minutes to about 80 minutes, about 50 minutes to about 70 minutes, or at about 30 minutes, about 35 minutes, about 40 minutes, about 45 minutes, about 50 minutes, about 55 minutes, about 60 minutes, about 65 minutes, about 70 minutes, about 75 minutes, about 80 minutes, about 85 minutes or about 90 minutes.

In some embodiments, the n-GaAs₁₋ₓSbₓ core may have a diameter ranging from about 60 nm to about 85 nm, about 65 nm to about 80 nm, or from about 70 nm to about 75. In some embodiments, the n-GaAs₁₋ₓSbₓ core may have a length ranging from about 1.0 μm to about 1.5 μm. In various embodiments, x may range from about 0.2 to about 0.4. In various embodiments, to provide a gradient of n-GaAsSb, a second n-GaAs_{1-y}Sb_{y} core comprising a different Sb content (y) may be grown on top of the first n-GaAsSb, n-GaAs₁₋ₓSbₓ core forming a continuous core configuration with multiple “core segments.” In some embodiments, n-GaAs_{1-y}Sb_{y} may have y ranging from about 0.2 to about 0.3. In various embodiments, the first and the second core segments may have same or substantially same diameter/thickness. In some embodiments, a continuous core configuration may comprise three core segments with varying Sb content in the n-GaAsSb core. In some embodiments, a third n-GaAs_{1-z}Sb_{z} core comprising a different Sb content (z) compared to n-GaAs₁₋ₓSbₓ and n-GaAs_{1-y}Sb_{y} to may be grown on top of the second n-GaAsSb (n-GaAs_{1-y}Sb_{y}) core forming a continuous core configuration with multiple “core segments.” In some embodiments, n-GaAs_{1-z}Sb_{z} may have z ranging from about 0.2 to about 0.3.

The core growth is then terminated by consuming the Ga droplet for about 5 minutes to about 15 minutes, about 7 minutes to about 13 minutes, about 9 minutes to about 11 minutes, or about 5 minutes, about 6 minutes, about 7 minutes, about 8 minutes, about 9 minutes, about 10 minutes, about 11 minutes, about 12 minutes, about 13 minutes, 14 minutes, or about 15 minutes at a temperature ranging from about 450° C. to about 475° C., about 455° C. to about 470° C., about 460° C. to about 465° C., or at about 455° C., about 460° C., about 465° C., about 470° C., or about 475° C. by closing all shutters except As source.

After the core growth, in some embodiments, an intrinsic-GaAs₁₋ₐSbₐ (i-GaAs₁₋ₐSbₐ) shell may be grown on the surface of the core in a configuration such that the shell encloses or overcoats the core. In various embodiments, the shell may be grown by depositing precursor sources comprising Ga, As, Sb, and intermittent GaTe supply. As used herein, “intermittent GaTe supply” may refer to introducing GaTe supply at a defined duration or pulse. In some embodiments, for a 10-minute growth of i-GaAsSb NW, GaAsSb may be grown for about 2 minutes, and n-GaAsSb (by introducing GaTe) for 2 seconds. In some embodiments, GaTe may be applied for 10 minutes at 2 minutes/2 seconds GaAsSb/n-GaAsSb pulse cycles. In some embodiments, for a 5-minute growth of i-GaAsSb NW, GaAsSb may be grown for about 1 minutes, and n-GaAsSb (by introducing GaTe) for 2 second. In some embodiments, GaTe may be applied for 5 minutes at a 1 minutes/2 seconds GaAsSb/n-GaAsSb pulse cycles. In some embodiments, intermittent GaTe supply may be provided by applying GaTe source at a constant pulse every 1 second, 2 seconds, 3 seconds, about 4 seconds, or 5 seconds. In some embodiments, Ga source may be introduced at BEP of about 1.0×10⁻⁷ torr to about 2×10⁻⁷ torr, As source may be introduced at BEP of about 1.85×10⁻⁶ torr, and Sb source may be introduced at BEP of about 7.92×10⁻⁷ torr. The i-GaAs₁₋ₐSbₐ shell may be grown at a temperature ranging from about 500° C. to about 600° C., about 510° C. to about 590° C., about 520° C. to about 580° C., about 530° C. to about 570° C., about 540° C., about 560° C., or at about 500° C., about 510° C., about 520° C., about 530° C., about 540° C., about 550° C., about 560° C., about 570° C., about 580° C., about 590° C., or at about 600° C. In some embodiments, the intrinsic-GaAs₁₋ₐSbₐ (i-GaAs₁₋ₐSbₐ) shell may be grown at duration ranging from about 35 minutes to about 50 minutes. In some embodiments, i-GaAs₁₋ₐSbₐ shell may have a ranging from about 0.25 to about 0.3. In some embodiments, the i-GaAs₁₋ₐSbₐ shell may have a thickness ranging from about 25 nm to about 50 nm, about 30 nm to about 45 nm, or about 35 nm to about 40 nm.

In some embodiments, a second shell comprising p-type GaAs_{1-b}Sb_{b} (also referred to as p-GaAs_{1-b}Sb_{b}) shell that encloses the first i-GaAs₁₋ₐSbₐ shell. In various embodiments, the shell may be grown by depositing precursor sources comprising Ga, As and Sb. In some embodiments, Ga source may be introduced at BEP of about 1.0×10⁻⁷ torr to about 2×10⁻⁷ torr, As source may be introduced at BEP of about 1.5×10⁻⁶ torr to about 5×10⁻⁶ torr, and Sb source may be introduced at BEP of about 5.28×10⁻⁷ torr. In some embodiments, GaAsSb may be doped with a p-type dopant, such as beryllium (Be), and may be introduced at a Be cell temperature of 930°. The p-GaAs_{1-b}Sb_{b} shell may be grown at a temperature ranging from about 500° C. to about 600° C., about 510° C. to about 590° C., about 520° C. to about 580° C., about 530° C. to about 570° C., about 540° C., about 560° C., or at about 500° C., about 510° C., about 520° C., about 530° C., about 540° C., about 550° C., about 560° C., about 570° C., about 580° C., about 590° C., or at about 600° C. In some embodiments, the i-GaAs₁₋ₐSbₐ shell may be grown at duration ranging from about 25 minutes to about 35 minutes. In some embodiments, p-GaAs_{1-b}Sb_{b} shell may have b ranging from 0.2 to 0.25. In some embodiments, the p-GaAs_{1-b}Sb_{b} shell may have a thickness ranging from about 25 nm to about 50 nm, about 30 nm to about 45 nm, or about 35 nm to about 40 nm.

In some embodiments, an AlGaAs/GaAs passivation layer/shell may be grown on surface of outermost shell by depositing precursor comprising Al, Ga, and As. In some embodiments, Al source may be introduced at cell temperature from about 980° C. to about 1020° C., about 985° C. to about 1015° C., about 990° C. to about 1010° C., about 995° C. to about 1005° C., or at about 1000° C. In some embodiments, Ga source may be introduced from BEP of about 1.0×10⁻⁷ torr to about 2×10⁻⁷ torr, and As source may be introduced from BEP of about 1.5×10⁻⁶ torr to about 5×10⁻⁶ torr. In some embodiments, the passivation layer may be grown at a temperature ranging from about 450° C. to about 470° C., about 455° C. to about 465° C., or at about 450° C., about 455° C., about 460° C., about 465° C., or at about 470° C. In some embodiments, the AlGaAs/GaAs shell may be grown at duration ranging from about 5 minutes to about 10 minutes, or at about 5 minutes, 6 minutes, 7 minutes, 8 minutes, 9 minutes, or at about 10 minutes. In some embodiments, the AlGaAs/GaAs passivation layer may have a thickness ranging from about 10 nm to about 25 nm, about 12 nm to about 23 nm, about 14 nm to about 21 nm, or about 16 nm to about 19 nm.

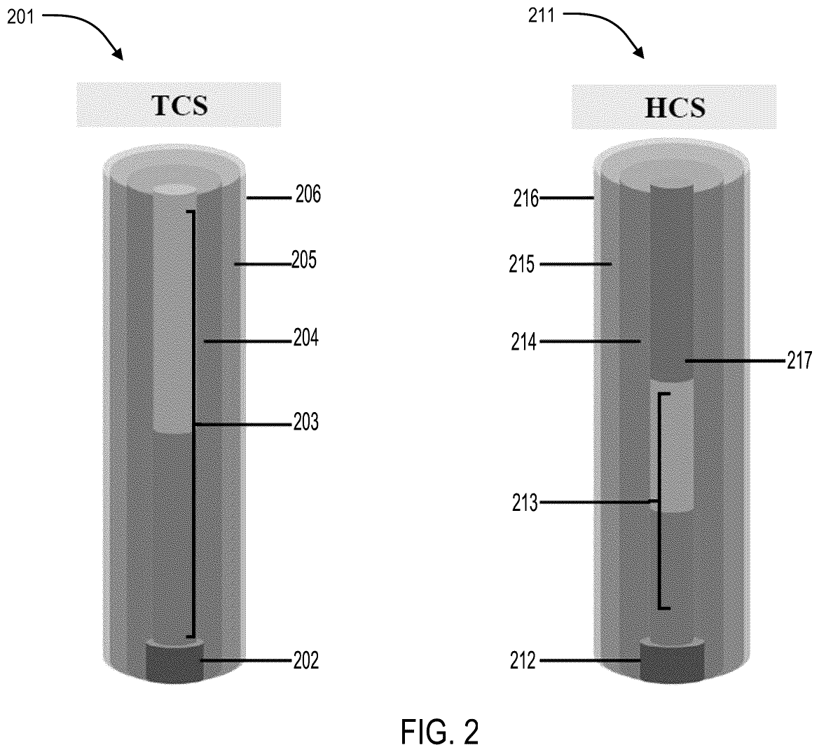

In another aspect embodiment, an ensemble of hybrid core shell (HCS) n/i-i-p GaAsSb NW 130 may be grown by the disclosed method. As used herein and discussed above, the “n/i” represents the n-type core and the i-type axial core extending vertically from the surface of the graphene substrate and “i-p” represents the i-type and p-type shell component of HCS NW. As seen in FIG. 2., the primary difference between the TCS 201 and HCS 211 architectures is the axial core segments of the NW structure. In some embodiments, the TCS structure is grown with one or more n-GaAsSb core, whereas the HCS structure is grown with a hybrid core comprising both axial n-GaAsSb segment with or without i-GaAsSb “core” segments. In some embodiments, HCS growth may comprise same n-GaAsSb stem, first shell, second shell, and passivation layer growth steps as described above in the growth of i-GaAsSb NW and TCS NW. In various embodiments, the length HCS or TCS NWs may range from about 800 nm to about 2500 nm, about 1000 nm to about 2200 nm, about 1200 nm to about 2000 nm, about 1400 nm to about 1800 nm, or about 1600 nm. In some embodiments, diameter of HCS or TCS NWs may range from about 120 nm to about 300 nm, about 140 nm to about 280 nm, about 160 nm to about 260 nm, about 180 nm to about 240 nm, about 200 nm to about 220 nm.

In some embodiments, TCS 201 (HCS 211) may comprise n-GaAsSb stem 202 (212). In some embodiments, n-GaAsSb core 203 (213) may be grown axially from stem 202 (212). As seen in FIG. 2, in some embodiments, n-GaAsSb core 203 (213) may comprise one or more “segment” containing different percentage of Sb component. In some embodiments, TCS (HSC) may comprise a first shell 204 (214). In some embodiments, first shell 204 (214) may comprise i-GaAsSb. In some embodiments, second shell 205 (215), comprising p-doped GaAsSb (p-GaAsSb) may enclose around first shell 204 (214). In some embodiments, TCS (HSC) may comprise an outermost passivation layer 206 (216) enclosing second shell 205 (215). In some embodiments, passivation layer 206 (216) may comprise AlGaAs/GaAs. In various embodiments, HCS 211 may further comprise an i-GaAsSb core segment 217 grown on top of n-GaAsSb core 213 that provides enhanced absorption volume and minimize interface effects and prevent Schottky diode formation.

In various embodiments, n/i-i-p GaAsSb NW 130 (as seen in FIG. 1) or 211 (as seen in FIG. 2) may comprise more than one n-GaAsSb core (e.g., n-GaAs₁₋ₓSbₓ, n-GaAs_{1-y}Sb_{y}, or n-GaAs_{1-z}Sb_{z}) with a V/III (i.e., As to Ga or Sb to GA) BEP ratio ranging from about 15 to about 25, or at about 15, about 16, about 17, about 18, about 19, about 20, about 21, about 22, about 23, about 24 or about 25. In some embodiments, n-GaAsSb core may be grown at a temperature ranging from about 550° C. to about 600° C., about 555° C. to about 595° C., about 560° C. to about 590° C., about 565° C. to about 585° C., about 570° C., about 580° C., or at about 550° C., about 555° C., about 560° C., about 565° C., about 570° C., about 575° C., about 580° C., about 585° C., about 590° C., about 595° C., or at about 600° C. In some embodiments, the n-GaAs₁₋ₓSbₓ core is grown at duration ranging from about 30 minutes to about 90 minutes, about 40 minutes to about 80 minutes, about 50 minutes to about 70 minutes, or at about 30 minutes, about 35 minutes, about 40 minutes, about 45 minutes, about 50 minutes, about 55 minutes, about 60 minutes, about 65 minutes, about 70 minutes, about 75 minutes, about 80 minutes, about 85 minutes or about 90 minutes. In some embodiments, n-GaAs₁₋ₓSbₓ may have x ranging from 0.2 to 0.4, n-GaAs_{1-y}Sb_{y} may have y ranging from 0.2 to 0.3, and n-GaAs_{1-z}Sb_{z} may have z ranging from 0.2 to 0.3.

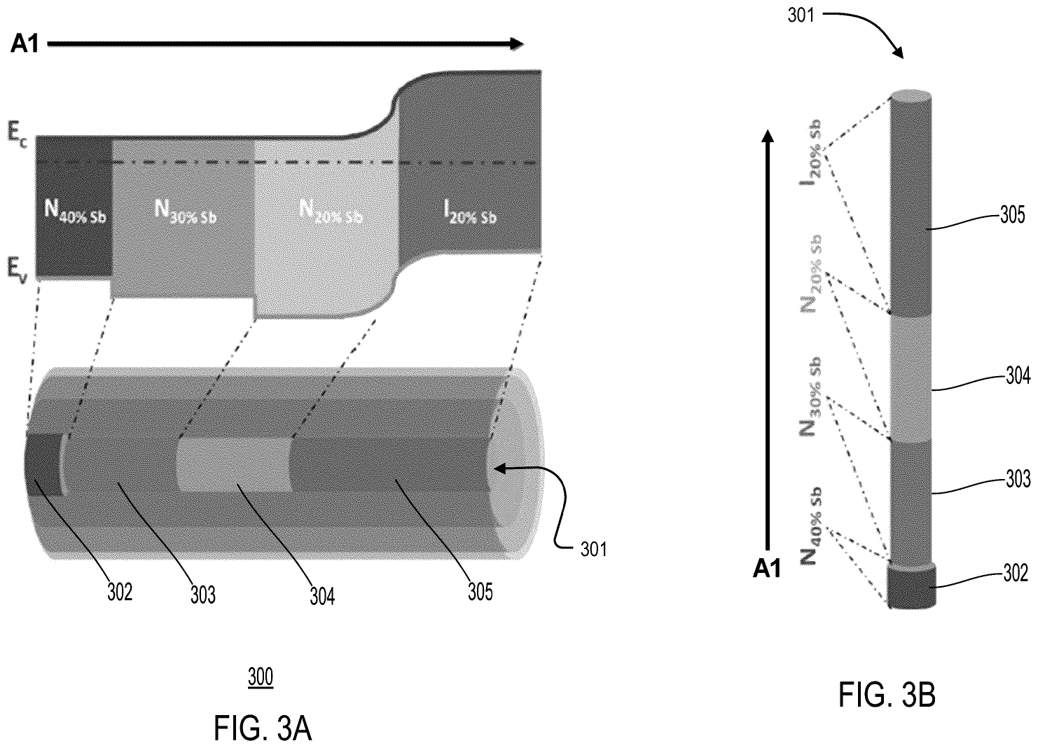

In some embodiments, HCS 300 may comprise one or more layers or segments of n-GaAsSb core (e.g., n-GaAs₁₋ₓSbₓ, n-GaAs_{1-y}Sb_{y}, or n-GaAs_{1-z}Sb_{z}) grown in a configuration such that there is a decreasing linear (along growth axis) gradient of n-type GaAsSb along the axial core as seen in FIGS. 3A and 3B. In some embodiments, axial core-shell NW (TCS or HCS) 300 may comprise more than one n-doped segments 303 and 304 along NW core 301 grown axially along axis Al from stem 302. In various embodiments, stem 302 may comprise highest Sb percentage (i.e., 40%), segment 303 may comprise highest percentage of Sb (i.e., 30%), and segment 304 may comprise Sb percentage of 20%. In some embodiments, an HCS configuration may further comprise segment 305 comprising an i-GaAsSb having an Sb percentage of 20%. This configuration promotes uniform, controlled growth, and enables bandgap engineering such that as the Sb decreases along axial direction, the band gap (i.e., energy gap between the valence band Er and the conduction band E_{c}), increase allowing for electronic tunability along the longitudinal axis of the core and the NW. In some embodiments, this approach reduces strain accumulation and abrupt interface defects caused by composition changes, resulting in NWs with improved crystalline quality that is essential for high-performance optoelectronic devices.

In some embodiments, an intrinsic-GaAsSb (i-GaAsSb) top segment (305) may be grown by introducing V/III BEP ranging from about 15 to about 25, or at about 15, about 16, about 17, about 18, about 19, about 20, about 21, about 22, about 23, about 24 or about 25. In some embodiments, i-GaAs_{1-z}Sb_{z} segment may be grown at a temperature ranging from about 550° C. to about 600° C., about 555° C. to about 595° C., about 560° C. to about 590° C., about 565° C. to about 585° C., about 570° C., about 580° C., or at about 550° C., about 555° C., about 560° C., about 565° C., about 570° C., about 575° C., about 580° C., about 585° C., about 590° C., about 595° C., or at about 600° C. In some embodiments, the i-GaAsSb may be intrinsic-GaAs₁₋ₙSbₙ (i-GaAs₁₋ₙSbₙ) core is grown at duration ranging from about 15 minutes to about 30 minutes. In some embodiments, i-GaAs₁₋ₙSbₙ may have n ranging from 0.15 to 0.2.

In some embodiments, after the growth of i-GaAsSb segment, the core growth may be terminated and one or more GaAsSb shell (e.g., i-GaAsSb and/or p-GaAsSb) and/or AlGaAs/GaAs passivation layer may be grown using the method described above. In some embodiments, NWs may be grown in an array or an ensemble having NW density (number of NWs over a substrate area) may by between from about 25 μm² to about 70 μm⁻², about 30 μm² to about 65 μm⁻², about 35 μm² to about 60 μm⁻², about 40 μm² to about 55 μm⁻², or about 45 μm⁻² to about 50 μm⁻².

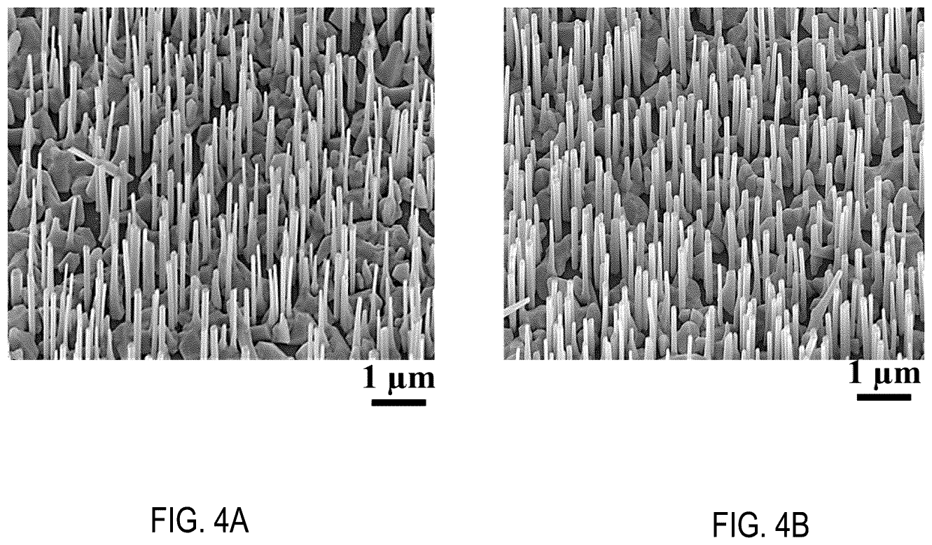

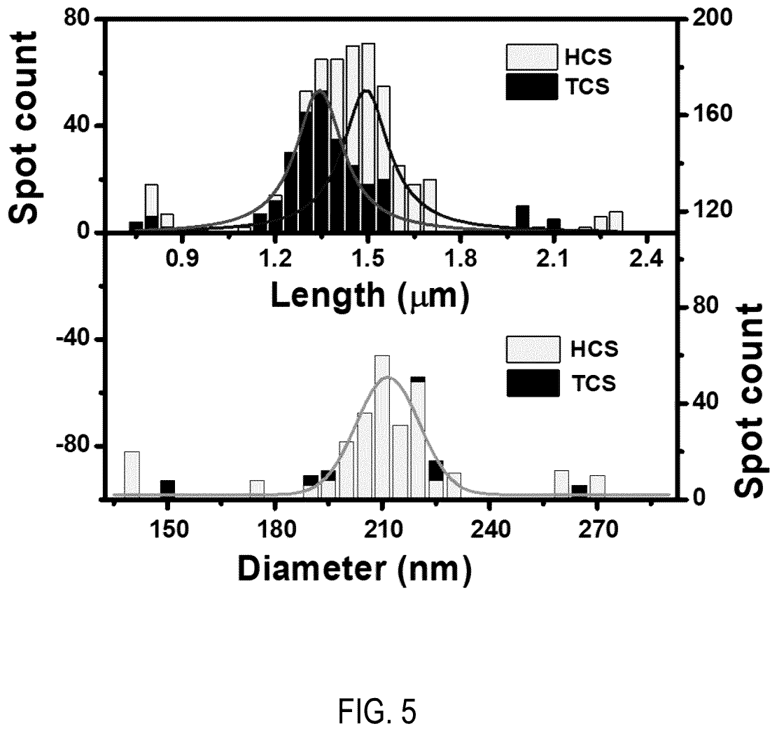

FIGS. 4A and 4B illustrates SEM images of high-density, TCS and HCS NW structures produced from the disclosed method indicating high-density vertical growth of the two NW configurations. As shown in FIG. 5, average length and diameter of TCS and HCS NW structures are shown to be from about 1.35 μm and about 1.5 μm, respectively, with a comparable average diameter of about 210 nm between the two architectures.

The NWs were then configured into a NW photodetector (NW PD) by spin-coating the NW ensemble with SU-8 polymer, and the tips of the NWs were exposed by etching the polymer with deep reactive ion etching (DRIE). Silver NWs were sprayed through a circular mesh on top of exposed tips for the top contact and silver paste on the monolayer graphene substrate for the bottom contact.

### EXAMPLES

The following examples have been included to provide guidance to one of ordinary skill in the art for practicing representative embodiments of the presently disclosed subject matter. In light of the present disclosure and the general level of skill in the art, those of skill can appreciate that the following Examples are intended to be exemplary only and that numerous changes, modifications, and alterations can be employed without departing from the scope of the presently disclosed subject matter.

### Experimental Detail

A two-temperature growth process was employed for GaAsSb core growth, starting with a low substrate temperature (T_{L}) for n-GaAsSb stem growth of high Sb composition (>0.2) followed by a high substrate temperature (T_{H}) for i-GaAsSb (Sb composition=0.2) core growth During the stem growth, Te dopant was introduced with Sb to utilize Te's surfactant property, precisely controlling the droplet angle, and reducing the formation of horizontal NWs and 2D crystallites on the graphene surface. To enhance the GaAsSb NW density on the monolayer graphene, the effect of variation in the growth parameters, namely pausing T_{L} for specific duration (hereafter referred to as pausing duration), V/III BEP ratio, and plasma duration, were investigated, as follows.

### Temperature Effect

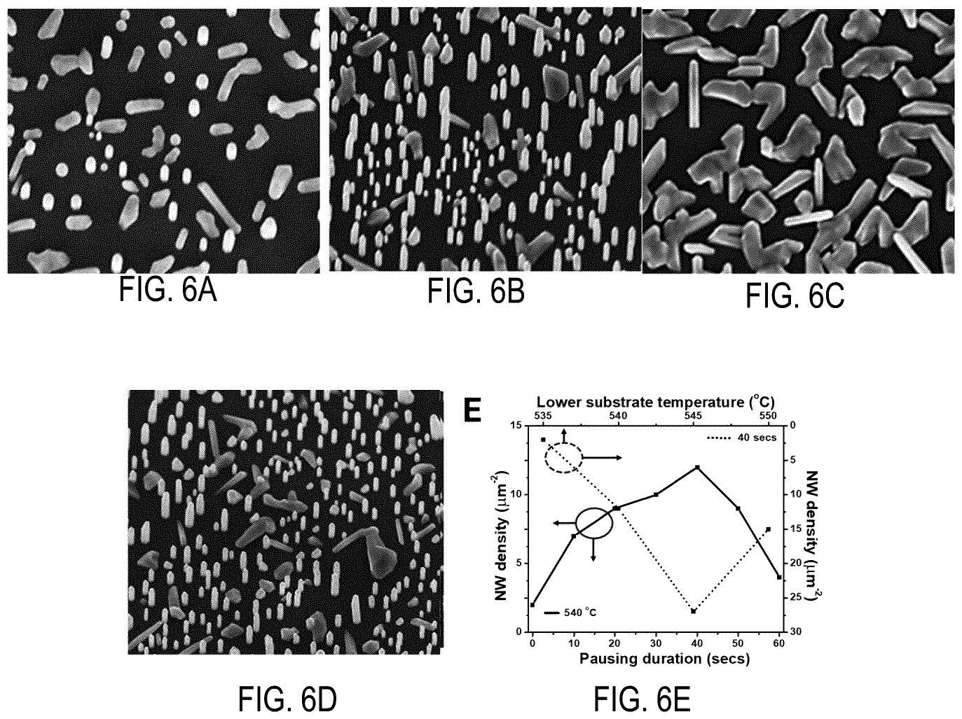

For the first growth set, the graphene was treated with O₂-plasma treatment at 1 W for 45 sec. Initially, the T_{L} variation for stem GaAsSb growth was examined in the 535° C.-550° C. range with pausing duration varying from 0 to 60 sec while maintaining the T_{H} of 580° C. for i-GaAsSb core variant. Immediate ramping from T_{L} (started with 540° C.) to T_{H} resulted in ample spherical Ga particles with large contact angles and few short NWs (NW density of ˜4 μm⁻²) as shown in FIG. 6A (scale bar is 0.5 μm). This signifies unfavorable nucleation due to nonwetting of the Ga droplet on the substrate surface. On increasing the pausing duration after opening the cell shutters in intervals of 10 sec to 40 sec resulted in an enhanced NW density (FIG. 6B) that is attributed to the increased wettability of Ga at lower temperatures due to increased nucleation probability with smaller contact angles. However, higher pausing duration (>40 sec) resulted in coarse NWs with reduced density and increased 2D growth (FIG. 6C). The pausing duration of 40 sec and T_{L} of 540° C. yielded an optimum NW density of ˜12 μm² (FIG. 6B).

With the optimized pausing duration of 40 sec, the impact of T_{L} between 535° C. and 550° C. was investigated. T_{L} of 535° C. resulted in increased parasitic growth, ascribed to agglomeration of Ga droplets. On the other hand, increasing the temperature to 545° C. exhibited an improved density of ˜27 μm² with reduced 2D growth (FIG. 6D). This is likely due to diffusion on the graphene surface and an increased Ga desorption rate, thus suppressing the 2D growth with improved nucleation rate. A further increase in T_{L} to 550° C. had an adverse effect on the NW yield, setting the lower bound for the narrow window of growth substrate temperature. FIG. 6E shows the graphical representation of NW density for different pausing durations and T_{L} data. Thus, the substrate temperature significantly alters the NW density.

### Effect of O₂-Plasma

Next, O₂-plasma exposure duration was investigated as the variable to determine its effects on the NW density. O₂-plasma exposure durations between 60 sec to 90 sec were examined for a constant RF power of 1 W, which was kept intentionally low to minimize any degradation in optoelectronic properties of graphene while creating sufficient oxygen-associated functional groups to enhance the surface wettability. The effect of plasma durations on the formation of specific functional groups was analyzed using XPS by measuring their binding energies. These were then correlated to the relative intensity of the defect-related Raman spectral modes and the NW density.

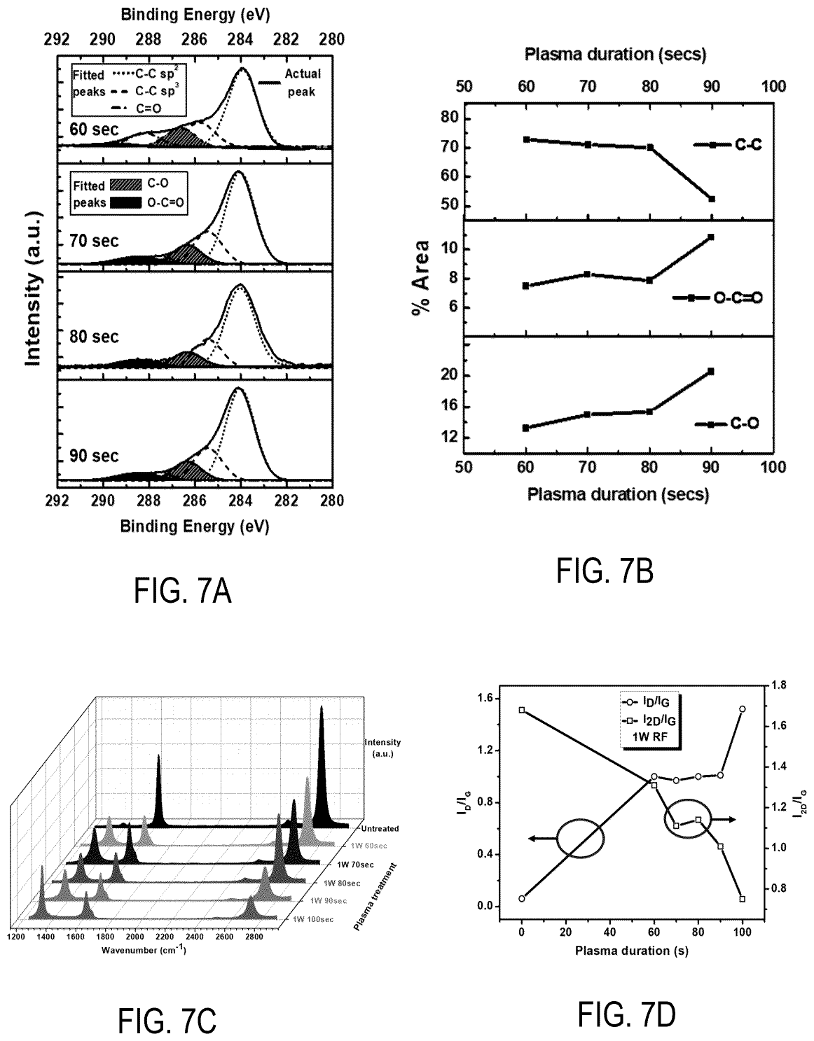

It has been observed that the O₂-plasma treatment of graphene facilitates the binding of reactive oxygen species with carbon atoms of the graphene lattice, resulting in various oxygen-containing functional groups that impact the wettability and Ga droplet contact angles such as C—O and O—C═O on the graphene surface. Functionalization of graphene surface with mild O₂-plasma power for a short duration significantly affected the Raman peaks by enhancing the D peak and lowering the 2D peak due to the influence of the induced O₂ functional groups. The XPS C 1s spectra of graphene as seen in FIG. 7A reveal that the binding energy peaks of C—O and O—C═O are positioned at ˜286.6 eV and ˜289 eV, respectively. The areal coverage of these two bonds increased as plasma duration increased from 60 sec to 90 sec, as shown in FIG. 7A (solid shade) and FIG. 7B. However, the C—C bond representative of a combination of sp² and sp³ bonds decreased (FIGS. 7A and 7B). These are summarized in the table below.

TABLE 1
Comparison of the corresponding bond's % area
between under various plasma treatment conditions.

| | % Area under the curve | | |
|---|---|---|---|
| | C—C (sp² and sp³) | O—C═O | C—O |
| Plasma Treatment | bonds | bond | bond |
| Pristine Monolayer Graphene | 89.2 | 1.07 | — |
| (untreated) | | | |
| 1 W and 60 Second treatment | 72.82 | 7.49 | 13.26 |
| 1 W and 90 Second treatment | 52.36 | 10.85 | 20.58 |

Now referring to FIG. 7C, Raman peaks assessed after each plasma duration revealed an increasing D peak intensity with increasing plasma duration, suggesting the formation of defects on the graphene surface. A plasma duration of 90 sec resulted in a significant enhancement in both the (I_{D}/I_{G}) and (I_{2D}/I_{G}) ratios as shown in FIG. 7D. The (I_{2D}/I_{G}) ratio, which pertains to the sp²- and sp³-hybridized C—C bonds exhibited a monotonic decrease with O₂-plasma exposure duration, while the (I_{D}/I_{G}) ratio related to O—C═O and C—O composition bonds exhibited a substantial increase for 60 second exposure and thereafter saturating until 90 seconds. For durations exceeding 90 seconds, a significant change in all three types of bonding was noted. A further increase in O₂-plasma exposure led to parasitic growth with reduce density, stemming from degradation of graphene surface by the O₂-plasma leading to a near complete wetting of the Ga droplets on graphene surface leading to non-vertical growth along the surface of the substrate.

The lowering of the Raman 2D peak with a corresponding rise in the D peak with plasma duration is ascribed to the oxygen atoms knocking out more of the carbon bonds on the graphene surface with prolonged plasma duration. Thus, based on Raman and XPS analysis, an O₂-plasma treatment duration of 90 seconds was chosen that provides more nucleation sites while having minimal effect on the graphene's optoelectronic properties.

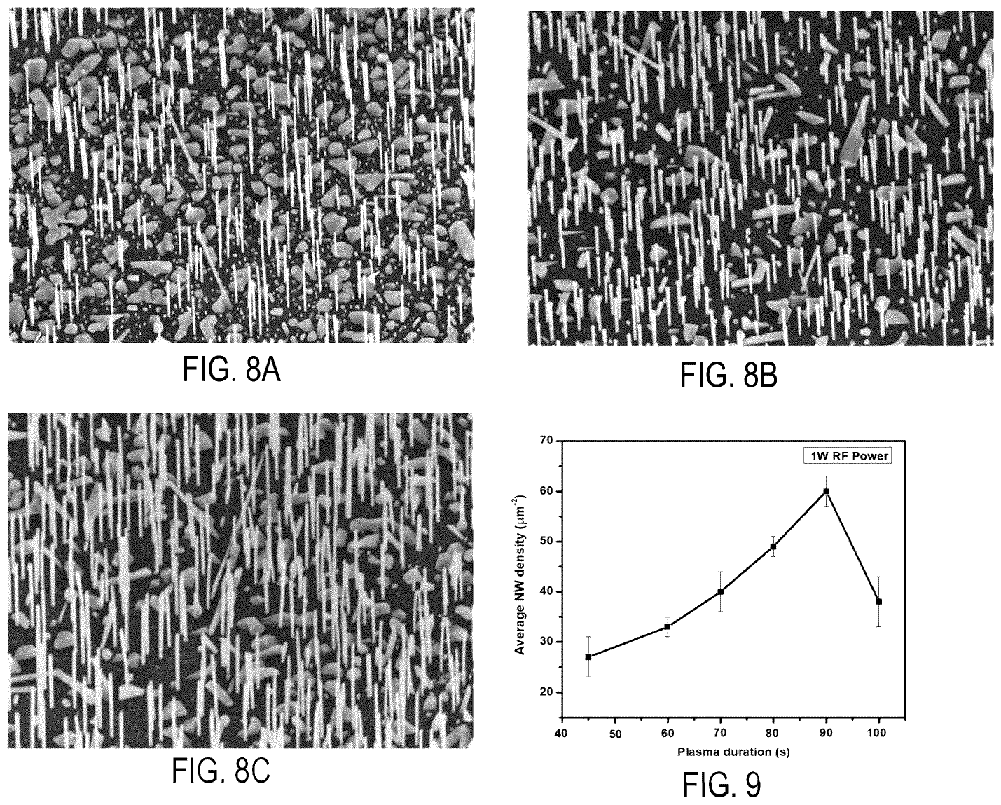

The scanning electron microscope (SEM) images of i-GaAsSb NWs on the plasma treated samples for different O₂-plasma treatment durations is shown in FIGS. 8A-8C (scale bar at 0.5 μm). FIG. 8A corresponds to O₂ exposure of 60 seconds, FIG. 8B corresponds to O₂-exposure of 70 seconds, and FIG. 8C corresponds to O₂ exposure of 90 seconds. The images show significant suppression in the two-dimensional (2D) parasitic growth for increased plasma exposure duration with a concomitant increase in the NW density up to 90 seconds. This is consistent with the XPS and Raman data as shown in FIGS. 7A-7D, which showed significant change in oxygen-related functional groups for 90 seconds plasma exposure, indicating increased nucleation sites. Thus, the reduction in the contact angle and more nucleation sites lead to minimal 2D growth with NW density increasing from about 25 μm² to about 60 μm⁻² as shown in FIG. 9, which is an increase of more than 10-fold compared to previously reported value.

### Effect of V/III Beam Equivalent Pressure (BEP) Ratio

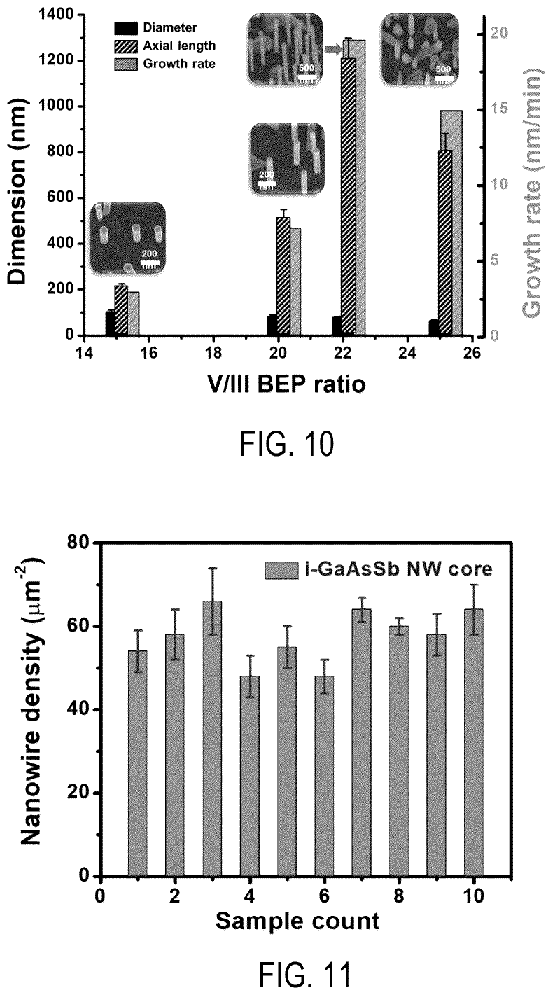

The last growth parameter for optimization was the V/III BEP ratio. As seen in FIG. 10, GaAsSb NW V/III BEP ratios of 15, 22, and 25 were investigated. The lower end of the BEP ratio of 15 yielded horizontal and short vertical NWs with a huge droplet on top, indicating the presence of excess Ga (FIG. 10). The upper end of BEP ratio of 25 resulted in growth termination in conjunction with increased 2D growth, caused by the group V-rich environment. The BEP ratio of 22 yielded optimal condition, which achieved an average axial length of ˜1.2 μm at a growth rate of ˜20 nm/min (FIG. 10). The GaAsSb NW density using the optimized parameters are shown in FIG. 11 indicating highly dense NW growth at BEP ratio of 22.

### Results and Discussion

### Photoluminescence (PL) Spectra of Doped GaAsSb.

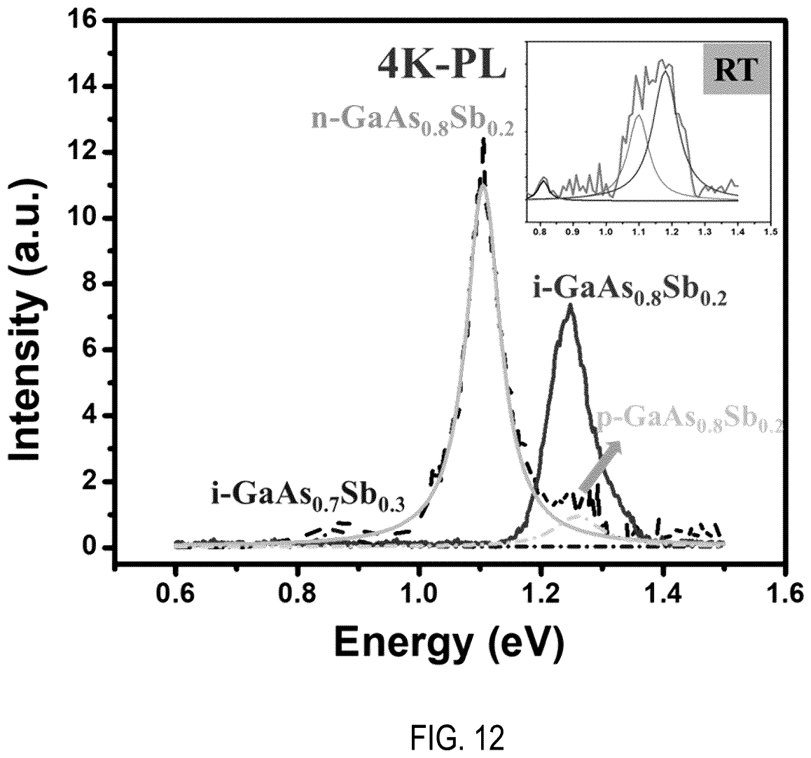

Referring to FIG. 12, a photoluminescence spectral (PL) of i-GaAsSb and n-GaAsSb NW measured at a temperature of 4 K are shown. As seen in FIG. 12, the PL spectra exhibited three peaks at ˜0.86 eV, 1.11 eV, and 1.24 eV, with FWHMs of ˜50 meV, 69 meV, and 88 meV, respectively, which are blue shifted to the respective deconvoluted PL peaks at room temperature (RT) (inset) at ˜0.81 eV, 1.09 eV, and 1.2 eV, with the corresponding FWHMs of ˜38 meV, 75 meV, and 91 meV, as expected due to the temperature-induced bandgap shift. The dominant high energy 4K PL peak at 1.11 eV is assigned to the n- and i-type hybrid core segments of the NW and two relatively weak peaks on either side are assigned to n- and p-segments, consistent with the different Sb compositions expected of radial segments. It should be noted that the i-GaAsSb core NW sample, sharing the same Sb composition as the n/i and p-doped segment in the HCS sample, has a 4K PL peak intensity and FWHM (˜79 meV) intermediate to the doped segments and intensity enhancement relative to the p-segment. The blue shift of the PL peak energy, increased PL intensity with low FWHM of the n/i core hybrid segment relative to both the shell i-GaAsSb NWs and p-GaAsSb NWs attests to the Te doping annihilation of the defects induced by acceptor vacancies leading to improved material quality of the core-segment.

### Transmission Electron Microscope (TEM) and Energy Dispersive X-Ray Spectroscopy (EDS) Analysis

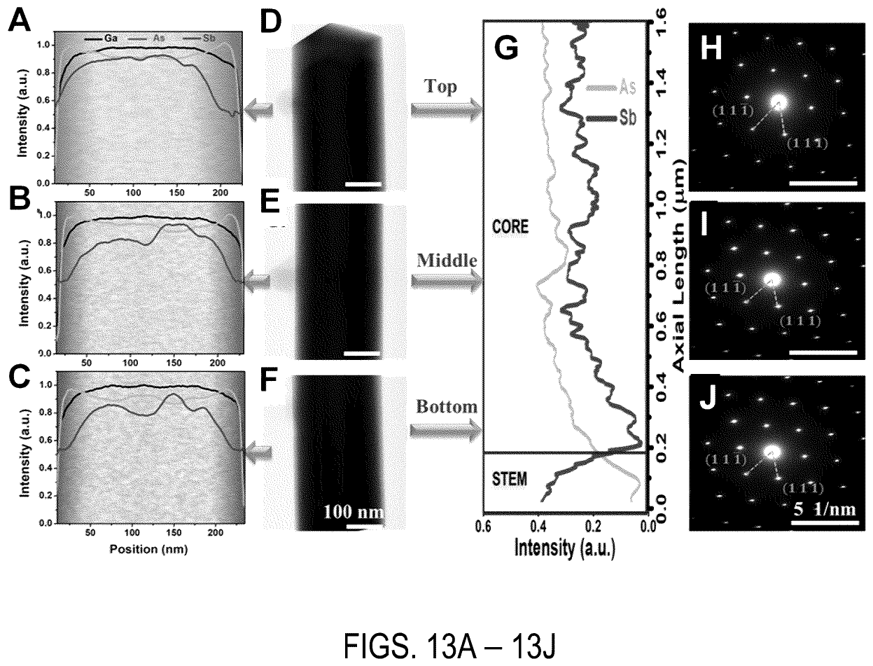

The EDS compositional line scans interlaced with mapping of high-angle angular dark-field (HAADF) scanning TEM (STEM) of an n-i-p GaAsSb NW HCS sample are shown in FIGS. 13A-13C. The spectra show a clear delineation of the Sb variation in shell topography with Sb composition being the highest in the intrinsic shell in the bottom and middle segment. However, Sb composition variation is smeared and no noticeable distinction between the intrinsic core and shell segment is observed on the top segment, very likely due to termination of the core, which occurs under As rich condition. FIGS. 13D-13F display the cross-sectional TEM images of GaAsSb, with the axial core's EDS compositional analysis presented in FIG. 13G, which reveals a clear distinction between the stem and core segments. The corresponding TEM images (FIGS. 13D-13F) and SAED patterns of individual segments (FIGS. 13H-13J) illustrate a pure zinc-blend (ZB) crystal structure with a high degree of phase purity devoid of twins and stacking faults. The high structural quality of NW even at the tip is attributed to vdW epitaxial growth on the graphene substrate, which facilitates large lattice mismatch materials to be tolerated with minimal interfacial stress leading to the enhanced diffusion of constituent elements.

### Contact-Atomic Force Microscopy (C-AFM) Analysis of a Single NW

As discussed in the experimental section, C-AFM was used to measure the single NW (SNW) I-V characteristics of both TCS and HCS structures. The results show a dark current of ˜30 pA and a photocurrent of 1 nA, respectively, at −1 V. However, at −1 V, the dark and photocurrent of the HCS structure were measured to be 15 pA and 2 nA, respectively. with a maximum photoresponse of 10 nA at −2 V. At a laser power intensity of 1 mW and beam spot area of 0.5 cm², the responsivity and detectivity were determined. TCS and HCS NW structures had responsivities of 56 mA/W and 110 mA/W, and detectivities of 1.5×10¹³ Jones and 3.6×10¹³ Jones at −1 V, respectively. The reverse bias dependencies of responsivity and detectivity of TCS and HCS structures exhibited a maximum responsivity of 0.57 A/W with a detectivity of 1.6×10¹⁴ Jones at −2 V, which is a 7-fold increase in responsivity and a 3-fold increase in detectivity than the HCS structure grown on Si.

### Current-Voltage (I-V) Properties of TCS and HCS NW Samples

Optoelectronic properties of both ensemble of TCS and HCS NW devices show the current-voltage (I-V) characteristics in the semi-logarithmic scale at RT of these devices under dark and different illumination conditions. Both structures exhibited rectifying behavior with a low dark reverse current density of about 0.2 μA/cm² at −1 V, an order of magnitude less than the one reported on Si grown under similar conditions. From C-AFM and I-V measurements, the reduced dark current is speculated to be due to the formation of a barrier junction between the O₂-plasma monolayer graphene substrate and GaAsSb NW interface, inhibiting the carrier transit, and/or the improved quality of NWs grown on graphene substrate with better carrier mobilities than conventional Si substrate.

Moreover, the HCS sample demonstrated a one-order higher on/off ratio of 5.5×10⁴ at −1 V, demonstrating the device's surprising and exceptional photosensitivity. The TCS and HCS samples exhibited diode resistances of about 6.3 kΩ and about 2.5 kΩ, and shunt resistances of about 0.9 GΩ and about 3 GΩ, respectively. The responsivity was calculated for incident power intensity ranging from 50 to 250 uW and multiplied with an area factor. The area factor is the ratio of the circular Ag NWs contact area to the entire laser illuminated area, where the circular diameter of the Ag NWs contact is 0.8 mm and that of the illuminated region is 1 cm.

Additionally, the TCS sample exhibited a responsivity of about 50 A/W and a detectivity of about 7.0×10¹¹ Jones at −1 V for 1500 nm. The HCS sample exhibited higher responsivity and detectivity of about 2100 A/W and about 2.7×10¹⁴ Jones at −1 V, while the highest responsivity of about 1.3×10¹⁴ A/W was achieved at −3 V bias, at the expense of a slight decrease in detectivity to 1.5×10¹⁴ Jones. The spectral cutoff wavelengths of the TCS and HCS device at −1 V were measured to be ˜1.5 μm and ˜1.55 μm, respectively. It is evident that the effect of increased intrinsic thickness from the supplemental i-core results in a larger cutoff wavelength in the HCS structure, enhancing its sensitivity to higher wavelengths and improving both its responsivity and detectivity.

### Capacitance-Voltage (C-V) Properties of TCS and HCS NW Samples

The C-V measurements show a frequency-dependent behavior. As the voltage varies from 0 to −3 V at 1 KHz, the capacitance (C) of TCS and HCS NW samples drops from 1.1 pF to 0.7 pF and 0.4 pF to 0.3 pF, respectively, indicating the presence of trap levels within the intrinsic layer, a trend observed in other p-i-n designs. The HCS NW sample, with a smaller C-V slope and capacitance value at 1 kHz compared to TCS, attests to lower trap density, suggesting a faster time response and a wider depletion region. At higher frequencies of 10 kHz, a decreasing slope of C-V transitions to a bias-independent profile at 100 kHz for TCS, while the HCS sample's capacitance value remains invariant with voltage at both these frequencies, indicating minimal trap effects.

### Low-Frequency Noise (LFN) Analysis of TCS and HCS NW Samples

Low-frequency noise (LFN) analysis of TSC and HCS NW samples at −1 and −2 V measurements indicate distinct behaviors for TCS and HCS NW samples, with TCS having a corner frequency (f_{c}) of 10 Hz and HCS exhibiting a reduced f_{c} of ˜5 Hz. This behavior is indicative of dominant generation-recombination (G-R) noise in the TCS structure, as evidenced by higher power spectral density (PSD) level, consistent with the presence of deep-level traps. Beyond f_{c}, a steep 1/f dependence in the TCS corresponds to shallow trap-influenced G-R noise, while the HCS exhibits a flatter PSD (at −1 V), signifying a transition to white noise and diminished G-R noise. The lower f_{c} in the HCS with reduced PSD across the frequency range and the absence of 1/f flickering noise past f_{c}, in contrast to the TCS sample, suggests the reduced trap-states and enhanced charge carrier transport. These observations indicate that the intrinsic core layer within the HCS structure potentially offers a more uniform and low-defect pathway for the carriers, hence minimizing interaction with traps, which are associated with 1/f noise. The HCS sample's lower f_{c} correlates with its reduced capacitance observed in the C-V measurements, likely caused by the expanded depletion width from the additional axial i-core segment, which effectively mitigates shallow trap effects. Moreover, the presence of white noise and the subdued 1/f flickering noise at higher frequencies can be ascribed to defect compensation within the i-segment. Therefore, the optoelectronic properties of the TCS and HCS NW samples of ensemble GaAsSb NW PDs are significantly impacted by the structural design, as evidenced by the I-V, C-V, and LFN analyses. This positions the HCS configuration as a promising architecture for high-sensitivity PD applications.

Thus, among the two sets of samples, the HCS NW structure demonstrates superior characteristics, such as lower dark current, enhanced responsivity and detectivity, voltage-independent low capacitance across a wide frequency range along with reduced PSD and lower f_{c}. The insertion of an i-core segment in HCS is speculated to limit Te diffusion at the top interface between core and shell, reduces interface smearing, and improves carrier mobility by decreasing impurity-related scattering. While the presence of Te hinders Sb incorporation in the n-doped core, the HCS's unique i-core and i-shell interface allows for higher Sb diffusion, resulting in better spectral response. All these characteristics indicate that the addition of an i-segment in the core of the NW contributes to a substantial improvement in the performance of the n-i-p GaAsSb device.

Moreover, significant differences are observed in the growth and device characteristics of the structures grown on graphene to those grown on conventional Si substrate. The i-nature of the top axial segment, forming core-shell radial junctions with varying Sb compositions, i.e., GaAs_{1-z}Sb_{z}, wherein z varies at the core and the shells, is very likely to result in an expanded depletion region. This, combined with potential electron-plasmon coupling caused by the plasmonic effect of the graphene surface, is speculated to play a critical role in increased light absorption. Importantly, graphene's superior charge transport properties, along with the effective interface between the NW and graphene, are expected to improve collection efficiency, resulting in higher photocurrent.

Further, the 3D nature of the junction makes it quite complicated as there are multiple parallel junctions radially due to the gradient Sb composition of the n-segment and an additional i-segment in the axial core. The analysis of the axial segments' energy band structure, the compositional gradient in the n-core segment from higher to lower Sb composition, when combined with the axial i-core, creates a barrier for holes and hinders hole transport. This contributes to the reduction of the generation-recombination mechanism, as evidenced by the reduced dark current, lower PSD, and improved device sensitivity. The compositional gradient of Sb in the n/i axial core of GaAsSb NW, transitioning from 40% to 20% in n-type and 20% in i-type segment is prone to introduce compositional strain, potentially leading to strain-induced bandgap shrinkage. This very likely explains the 4K PL peak emission at a lower energy of 0.86 eV and achieving a spectral photoresponse to greater than 1500 nm on graphene.

Finally, the crystalline quality of the base segment on graphene is excellent despite its high Sb composition, which normally poses a growth challenge on Si. In addition, the growth rate with a comparable Ga flux was observed to be nearly double on graphene compared to Si, minimizing the consumption of Ga precursor. These results show that the low energy barriers caused by the weak vdW forces on the graphene surface, though cause poor Ga adhesion to the surface, aid in improved atomic surface mobility, allowing more atoms to migrate towards the NW surface and improving the material quality. The temperature-dependent I-V and noise characteristics, as well as voltage-independent C-V characteristics at low frequencies of 10 kHz, show that trap effects of GaAsSb NWs grown on graphene substrate are significantly lower than those grown on Si, attesting to an improved interface. These outcomes highlight the potential of bandgap engineering of heterostructure layers through compositional variation of GaAsSb on graphene and strategically using different NW architectures in the formation of n-i-p junctions to boost the performance of and optoelectronic devices photodetection platform as well showcase its potential to integrate with other 2D materials.

The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

The foregoing merely illustrates the principles of the disclosure. Any examples set forth in this specification are not intended to be limiting and merely set forth some of the many possible embodiments for the appended claims. Those skilled in the art will readily recognize various modifications and changes that may be made without following the example embodiments and applications illustrated and described herein, and without departing from the true spirit and scope of the following claims.

It will be appreciated by persons skilled in the art that the present invention is not limited to what has been particularly shown and described. Rather, the scope of the present invention is defined by the claims which follow. It should further be understood that the above description is only representative of illustrative examples of embodiments. The description has not attempted to exhaustively enumerate all possible variations. The alternate embodiments may not have been presented for a specific portion of the invention, and may result from a different combination of described portions, or that other un-described alternate embodiments may be available for a portion, is not to be considered a disclaimer of those alternate embodiments. It will be appreciated that many of those un-described embodiments are within the literal scope of the following claims, and others are equivalent.

All references cited and/or discussed in this specification are incorporated herein by reference in their entireties and to the same extent as if each reference was individually incorporated by reference.

What is claimed is:

1. A core-shell axial nanowire (NW) comprising:
a base and a tip;
a core extending along a NW axis from the base to the tip; and
a shell enclosing the core;
wherein the core comprises n-type GaAsSb,
wherein the core comprises more than one segment.

2. The core-shell axial NW of claim 1, wherein the shell comprises intrinsic-GaAs₁₋ₐSbₐ, wherein a is from about 0.25 to about 0.3.

3. The core-shell axial NW of claim 1, wherein the core comprises an Sb content gradient, wherein Sb content decreases from the base to the tip.

4. The core-shell axial NW of claim 3, wherein the core comprises three segments, wherein a first segment comprises Sb content of up to 40%, a second segment comprises Sb content of up to 30%, and a third segment comprises Sb content of up to 20%,
wherein the first segment is disposed at the base, the third segment is disposed at the tip, and the second segment is positioned between the first segment and the second segment.

5. The core-shell axial NW of claim 1, wherein the core further comprises a top segment comprising intrinsic-GaAs₁₋ₙSbₙ, wherein n is from about 0.15 to about 0.20.

6. The core-shell axial NW of claim 1, wherein the shell enclosing the core is a first shell and the core-shell axial NW further comprises a second shell encloses the first shell, wherein the second shell comprises p-type GaAs_{1-b}Sb_{b}, wherein b is from about 0.2 to about 0.25.

7. The core-shell axial NW of claim 6, further comprising a passivation layer enclosing the second shell, wherein the passivation layer is AlGaAs/GaAs.

8. A NW ensemble comprising at least one core-shell axial NW of claim 1, wherein the NW ensemble has a NW density from about 25 μm² to about 70 μm⁻².

9. A photodetector device comprising at least one core-shell axial NW of claim 1.

10. A method of fabricating a core-shell axial NW, the method comprising
(a) forming a NW stem on a growth substrate by depositing first precursor sources on the growth substrate;
(b) growing a NW core on the NW stem by depositing the first precursor sources;
(c) surrounding the NW core with a shell by depositing a second precursor sources on the NW core;
wherein the first precursor sources comprise gallium (Ga), arsenic (As), antimony (Sb), and gallium telluride (GaTe),
wherein the second precursor sources comprise gallium (Ga), arsenic (As), antimony (Sb), and intermittent gallium telluride (GaTe), and
wherein the NW core comprises more than one segment deposited sequentially on the NW stem.

11. The method of claim 10, wherein the growth substrate is monolayer graphene, wherein the monolayer graphene is pre-treated with oxygen plasma by exposing the growth substrate to oxygen plasma from about 60 seconds to about 100 seconds.

12. The method of claim 10, wherein the NW core comprises n-type GaAsSb, wherein the n-type GaAsSb has an Sb content gradient from a NW base to a NW tip, wherein Sb content decreases from a segment disposed at the NW base towards the tip.

13. The method of claim 10, before step (c), further comprising:
growing a top segment on top of the NW core by depositing the second precursor sources using molecular beam epitaxy to deposit the second precursor sources, wherein the top segment is intrinsic-GaAs₁₋ₙSbₙ, wherein n is from about 0.15 to about 0.20

14. The method of claim 10, wherein the shell comprises intrinsic-GaAs₁₋ₐSbₐ, wherein a is from about 0.25 to about 0.3.

15. The method of claim 10, after step (c) further comprising;
surrounding the shell with a second shell by depositing third precursor sources on the shell using molecular beam epitaxy to deposit the third precursor sources,
wherein the shell surrounding the core is a first shell, and
wherein the third precursor sources comprise gallium (Ga), arsenic (As), and antimony (Sb),
wherein the second shell is GaAsSb doped with beryllium (Be).

16. The method of claim 10, wherein the forming the NW stem of step (a) is carried out at a temperature ranging from about 530° C. to about 560° C. at a growth duration of about 5 minutes.

17. The method of claim 10, wherein the growing the NW core of step (b) is carried out at a temperature ranging from about 550° C. to about 600° C. at a growth duration of about 60 minutes.

18. The method of claim 10, wherein the growing the NW core of step (b) comprises depositing Ga at a beam equivalent pressure from about 1×10⁻⁷ Torr to about 2×10⁻⁷ Torr.

19. The method of claim 10, wherein the growing the NW core of step (b) comprises depositing As to Ga beam equivalent pressure ratio from about 15 to about 25 and depositing Sb to Ga beam equivalent pressure ratio from about 15 to about 25.

20. The method of claim 15, after the surrounding the shell with the second shell step, further comprising:
surrounding the second shell with a passivation layer by depositing fourth precursor sources on the second shell,
wherein the fourth precursor sources comprise aluminum (Al), gallium (Ga), and arsenic (As).

21. The method of claim 20, wherein the passivation layer is grown at temperature ranging from about 450° C. to about 470° C. at a growth duration of about 8 minutes.

22. The method of claim 20, wherein the depositing fourth precursor step comprises depositing Ga at a beam equivalent pressure from about 1×10⁻⁷ Torr to about 2×10⁻⁷ Torr or depositing As at a beam equivalent pressure from about 1.5×10⁻⁶ Torr to about 5×10⁻⁶ Torr.
